(19) United States
(12) Patent Application Publication
(10) Pub. No.: US 2005/0082593 A1
(43) Pub. Date: Apr. 21, 2005

(54) Capacitor, method of manufacturing the same and memory device including the same

(75) Inventors: Jung-hyun Lee, Yongin-si (KR); Bum-seok Seo, Seoul (KR)

Correspondence Address: LEE & STERBA, P.C., SUITE 2000, 1101 WILSON BOULEVARD, ARLINGTON, VA, 22209, US

(73) Assignee: Samsung Electronics Co., Ltd.

(21) Appl. No.: 10/920,455

(22) Filed: Aug. 18, 2004

(30) Foreign Application Priority Data
Aug. 18, 2003 (KR) 2003-56857

(51) Int. Cl. H01L 21/00; H01L 21/8242; H01L 27/108; H01L 29/76

(52) U.S. Cl. 257/306; 438/3; 438/240; 257/310

(57) ABSTRACT

In a capacitor of a semiconductor device, a method of manufacturing the same and a memory device including the capacitor, the capacitor includes a lower electrode, a dielectric film on the lower electrode, an upper electrode on the dielectric film, and a first reaction barrier film for preventing a reaction between the lower electrode and the dielectric film, the first reaction barrier film being interposed between the lower electrode and the dielectric film.

### BACKGROUND OF THE INVENTION

1. Field of the Invention

The present invention relates to a semiconductor device and a method of manufacturing the same. More particularly, the present invention relates to a capacitor, a method of manufacturing the same and a memory device including the capacitor.

2. Description of the Related Art

In a capacitor of a semiconductor device, lanthanum oxide (La₂O₃) can be used as a dielectric film.

When a La₂O₃ film is deposited on a silicon (Si) layer, a silicate is formed in the capacitor as a result of a reaction between the La₂O₃ film and silicon of the Si layer. The formation of a silicate decreases characteristics of the capacitor.

As the integration density of semiconductor devices increases, capacitors must be formed that having a larger capacitance in a narrow region. The capacitance of a capacitor is proportional to a surface area of an electrode. Therefore, the capacitance of a capacitor can be increased by forming the electrode in three dimensions.

It is desirable that a thickness and a composition of a dielectric film are uniform even if the electrode of the capacitor has a complicated structure.

A conventional deposition method, such as a chemical vapor deposition (CVD) method, however, is not suitable for forming a dielectric film having a uniform thickness and composition on an electrode with a complicated structure due to process characteristics of the CVD method.

An atomic layer deposition (ALD) method for forming a thin film on a lower structure of a complicated structure has been introduced, in which a thin film with a desired composition can be deposited in a deep region of a complicated structure. The ALD method provides a uniformity of thickness and composition of a thin film to some degree.

Therefore, the ALD method can be used for forming a dielectric film having a uniform thickness and composition on a capacitor electrode having a complicated structure.

A La₂O₃ film can be formed using the ALD method. However, there is a possibility of characteristic changes of the La₂O₃ film resulting from absorption of water vapor (H₂O) when the La₂O₃ is exposed to the air because lanthanides are hygroscopic.

When forming an La₂O₃ film using the ALD method, after deposition of a lanthanum precursor layer, a large amount of water vapor can be absorbed by the lanthanum precursor layer during an oxidization process using water vapor (H₂O). In this case, electrical characteristics, such as an ability of the La₂O₃ film to prevent leakage current, can be degraded.

FIG. 1 is a graph illustrating an increase in a leakage current density when water vapor is used as an oxidation gas for forming various oxide films, such as an La₂O₃ film, using the ALD method. A first plot B1 represents a leakage current density of an aluminum oxide (Al₂O₃) film. A second plot B2 represents that of a hafnium oxide (HfO₂) film. Third through fifth plots B3, B4, and B5 represent leakage currents of precursors La(tmhd)₃, La(N(Si(Me)₃)₂)₃, and La(iPrCp)₃, respectively. As may be seen in FIG. 1, the leakage current density is greater for plots B3, B4, B5 of the lanthanum precursors as compared to plots B1 and B2, which are the Al₂O₃ film and the HfO₂ film, respectively.

### SUMMARY OF THE INVENTION

The present invention is therefore directed to a capacitor, a method of manufacturing the same, and a memory device including the same, which substantially overcome one or more of the problems due to the limitations and disadvantages of the related art.

It is a feature of an embodiment of the present invention to provide a capacitor, a method of manufacturing the same, and a memory device including the same, in which the capacitor is able to prevent an unwanted reaction between a dielectric film and a lower electrode on which the dielectric film is formed.

It is another feature of an embodiment of the present invention to provide a capacitor, a method of manufacturing the same, and a memory device including the same, in which the capacitor is able to prevent degradation of electrical characteristics of a dielectric film formed by an atomic layer deposition (ALD) by preventing the dielectric film from absorbing a large amount of water vapor.

At least one of the above and other features and advantages of the present invention may be realized by providing a capacitor of a semiconductor device including a lower electrode, a dielectric film on the lower electrode, an upper electrode on the dielectric film, and a first reaction barrier film for preventing a reaction between the lower electrode and the dielectric film, the first reaction barrier film being interposed between the lower electrode and the dielectric film.

At least one of the above and other features and advantages of the present invention may be realized by providing a semiconductor memory device including a capacitor connected to a transistor, wherein the capacitor includes a lower electrode, a dielectric film on the lower electrode, an upper electrode on the dielectric film, and a first reaction barrier film for preventing a reaction between the lower electrode and the dielectric film, the first reaction barrier film being interposed between the lower electrode and the dielectric film.

The lower electrode may be one of a silicon (Si) electrode doped with a conductive dopant and a titanium nitride (TiN) electrode.

The first reaction barrier film may have positive ions with smaller radii than positive ions of the dielectric film. The first reaction barrier film may be one of a hafnium oxide (HfO₂) film and an aluminum oxide (Al₂O₃) film.

The dielectric film may be an oxide film including a metal element, e.g., a lanthanide element. The dielectric film may have a thickness of between about 2 to 10 nm. The first reaction barrier film may have a thickness of about 2 nm. The dielectric film may have a thickness greater than that of the first reaction barrier film.

The upper electrode may be a titanium nitride (TiN) film. The capacitor may further include a second reaction barrier film between the upper electrode and the dielectric film, wherein the upper electrode is a silicon (Si) electrode doped with a conductive dopant. The second reaction barrier film may have positive ions with smaller radii than positive ions of the dielectric film. The second reaction barrier film may be one of a hafnium oxide (HfO₂) film and an aluminum oxide (Al₂O₃) film.

At least one of the above and other features and advantages of the present invention may be realized by providing a method of forming a capacitor including forming a lower electrode, forming a first reaction barrier film on the lower electrode, forming a precursor layer including a metal element on the first reaction barrier film, forming an oxide film including the metal element by oxidizing the precursor layer, drying the oxide film, and forming an upper electrode on the dried oxide film.

Forming the precursor layer may include depositing a precursor on the first reaction barrier layer. The precursor may be one of (La(tmhd)₃, La(N(Si(Me)₃)₂)₃ or La(iPrCp)₃.

Forming the first reaction barrier film may include forming an oxide film to a thickness of about 2 nm using an atomic layer deposition (ALD).

The first reaction barrier film may be one of hafnium oxide (HfO₂) and aluminum oxide (Al₂O₃).

The method may further include, before forming the upper electrode, forming a second reaction barrier film on the dried oxide film.

The lower electrode may be formed of a silicon (Si) electrode doped with a conductive dopant, and the upper electrode is formed of a titanium nitride (TiN) film. The lower electrode and the upper electrode may each be one of a silicon (Si) electrode doped with a conductive dopant and a titanium nitride (TiN) film. The lower and upper electrodes may be a titanium nitride (TiN) film.

The method may further include performing an exhaust process after forming the precursor layer, after forming the oxide film, or after drying the oxide film.

Forming the oxide film may include flowing an oxidation gas, which may be water vapor, over the precursor layer to firstly oxidize the precursor layer. Forming the oxide film may further include supplying ozone (O₃) over the firstly oxidized precursor layer to secondly oxidize the firstly oxidized precursor layer. In the formation of the oxide layer, the first and second oxidations may be repeated.

The metal element may be a lanthanide element.

Drying the oxide film may include flowing ozone (O₃) over the oxide film.

The first reaction barrier film and/or the second reaction barrier film may have positive ions with smaller radii than positive ions of the dielectric film. The first reaction barrier film and/or the second reaction barrier film may be one of a hafnium oxide (HfO₂) film and an aluminum oxide (Al₂O₃) film.

Since the capacitor according to an embodiment of the present invention prevents an unwanted reaction between a dielectric film, e.g., an La₂O₃ film, and the lower electrode, and prevents inclusion of a large amount of water vapor in the dielectric film while forming the dielectric film, degradation of electrical characteristics of the capacitor are prevented, thereby increasing the reliability of the semiconductor memory device including the capacitor.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a graph illustrating leakage current density with respect to thickness of a dielectric oxide film of a conventional capacitor for several types of dielectric oxide films;

FIGS. 2A-2C illustrate cross-sectional views of a capacitor according to various exemplary embodiments of the present invention;

FIG. 3 is a graph illustrating a leakage current density of the capacitor depicted in FIG. 2A with respect to a voltage applied to the capacitor;

FIG. 4 is a block diagram for describing each operation in the manufacture of a capacitor depicted in FIG. 2A according to an embodiment of the present invention;

FIG. 5 is a block diagram for describing a second operation in the manufacture of a capacitor depicted in FIG. 4; and

FIG. 6 illustrates a cross-sectional view of a semiconductor device including the capacitor depicted in FIG. 2A.

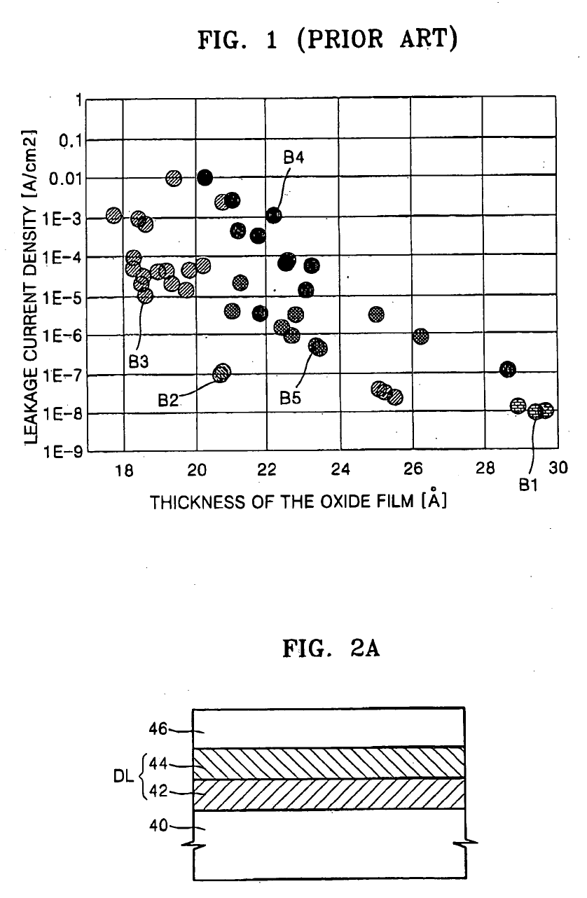

### DETAILED DESCRIPTION OF THE INVENTION

Korean Patent Application No. 2003-56857, filed on Aug. 18, 2003, in the Korean Intellectual Property Office, and entitled: “Capacitor, Method of Manufacturing the Same and Memory Device Including the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. Although the terms “dielectric film” and “oxide film” are used interchangeably in the context of the present invention, the term dielectric film is not intended to be limited to oxides and may be other dielectric materials.

A capacitor according to an exemplary embodiment of the present invention will now be described.

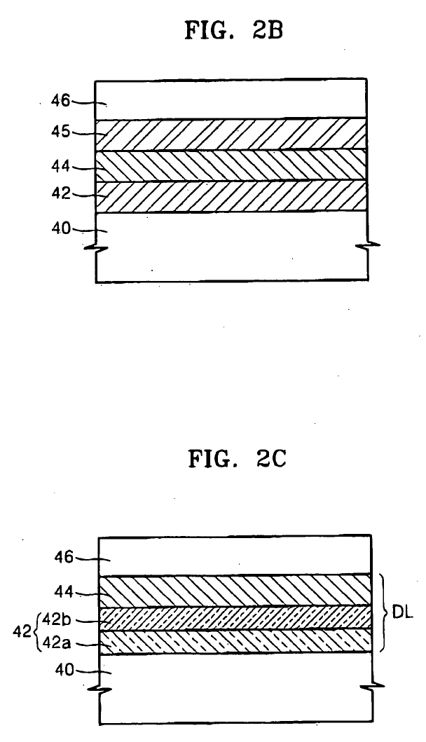

FIG. 2A illustrates a cross-sectional view of a capacitor according to an exemplary embodiment of the present invention.

Referring to FIG. 2A, the capacitor includes a lower electrode 40, a dielectric layer DL, and an upper electrode 46. The lower electrode 40 may be a silicon (Si) electrode doped with a conductive dopant or may be formed of titanium nitride (TiN). The dielectric layer DL includes a first dielectric film 42, which acts as a first reaction barrier film, and a second dielectric film 44. The first dielectric film 42 prevents an unwanted reaction between the lower electrode 40 and the second dielectric film 44. More specifically, the first dielectric film 42 prevents formation of a silicate. The first dielectric film 42 may be formed of a dielectric film including positive ions with smaller radii than those in the second dielectric film 44, such as a hafnium oxide (HfO₂) film or an aluminum oxide (Al₂O₃) film. The thickness of the first dielectric film 42 may be about 2 nm, or may be some other thickness that is thinner than the second dielectric film 44.

The second dielectric film 44 may be formed of an oxide film including a metal element, such as a lanthanum oxide (La₂O₃) film. The thickness of the second dielectric film 44 may be between about 2 to 10 nm, or may be thicker or thinner than this range. The upper electrode 46 may be a titanium nitride (TiN) electrode, or may be a Si electrode doped with a conductive dopant. In the latter case, however, as shown in FIG. 2B, a second reaction barrier film 45 that prevents a silicate reaction between the upper electrode 46 and the second dielectric film 44 can further be formed therebetween. The second reaction barrier film 45 may be similar to the first reaction barrier film. The upper electrode 46 and the lower electrode 40 can be formed of the same material.

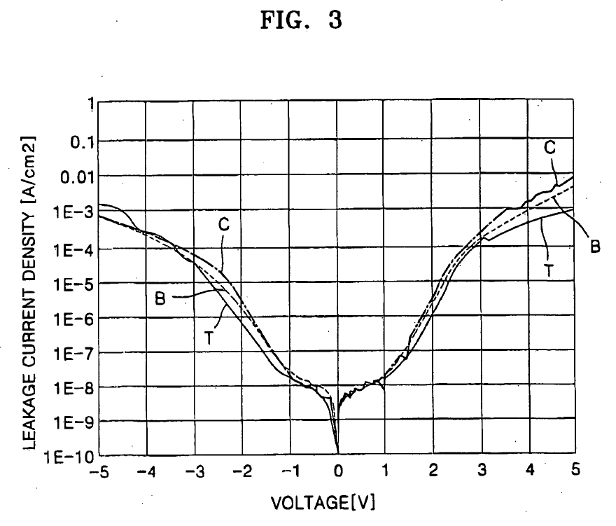

FIG. 3 is a graph illustrating a leakage current density with respect to a voltage applied to the capacitor according to an exemplary embodiment of the present invention. In FIG. 3, graphs T, B, and C represent leakage current densities of capacitors formed in an upper or top (T) part, a lower or bottom (B) part, and a middle or central (C) part of a wafer, respectively, when the wafer having the capacitors depicted in FIG. 2A, is vertically positioned.

Referring to the graphs T, B, and C, the capacitors formed on the upper, lower, and middle parts of the wafer show little difference in their leakage current densities, and the leakage current densities are lower than 1E-7 A/cm² within a driving voltage.

From the graphs T, B, and C, it may be seen that the capacitors formed on all regions of the wafer exhibit superior leakage current characteristics regardless of whether the capacitor is formed on the upper, lower, or middle part of the wafer.

A method of manufacturing the capacitor depicted in FIG. 2A according to an exemplary embodiment of the present invention will now be described.

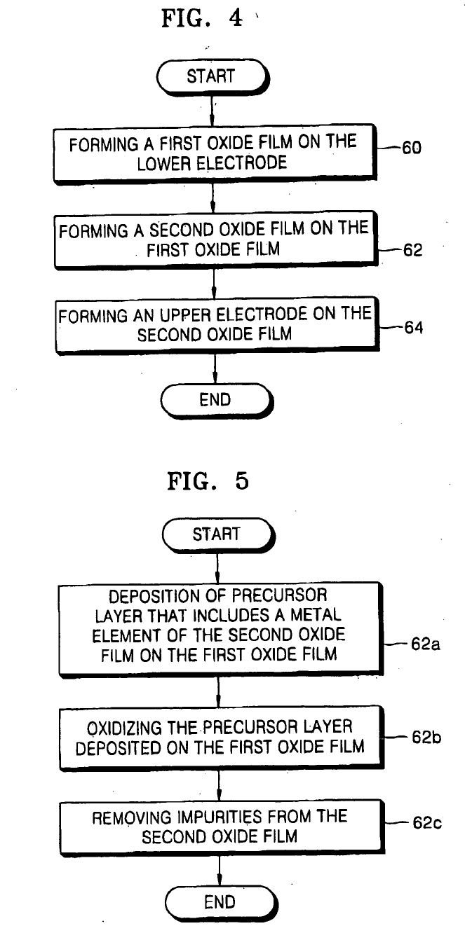

FIG. 4 is a block diagram for describing each operation in the manufacture of a capacitor depicted in FIG. 2A according to an embodiment of the present invention. In FIG. 4, the method of manufacturing the capacitor includes first through third operations 60, 62, and 64.

In the first operation 60, a first oxide film, which acts as a first reaction barrier film, is formed on the lower electrode. The lower electrode may be a Si electrode doped with a conductive dopant, or the lower electrode may be another conductive electrode, such as a TiN electrode. The first oxide film is used partly as a dielectric film of a capacitor, but primarily as a first reaction barrier film that prevents an unwanted reaction between a second oxide film, which will be formed later, and the lower electrode. Therefore, it is desirable that the dielectric film is formed without a component that can react with a component, i.e., silicon, included in the lower electrode. The thickness of the first oxide film may be about 2 nm, which is thinner than the second oxide film, but may also be thicker or thinner than 2 nm. Since the first oxide film is formed to a thickness of a few nanometers, the first oxide film may be formed using an ALD method in which thickness and composition can be controlled instead of a widely used thin film deposition method, such as a conventional CVD method. As shown in FIG. 2C, the first oxide film may be formed of a double layer film, which includes a lower layer 42a and an upper layer 42b. The first oxide film can be formed of an HfO₂ film and/or an Al₂O₃ film.

In the second operation 62, a second oxide film is formed on the first oxide film. The second oxide film performs the same function as the second dielectric film 44. Therefore, the second oxide film may be an oxide film including positive ions with larger radii than those in the first oxide film. The second oxide film may be formed of an oxide film including a metal element, such as an La₂O₃ film. The second oxide film may be formed to a thickness of a few nanometers like the first oxide film. However, the second oxide film may be formed to the same thickness or thicker than the first oxide film. Since the second oxide film is also formed to a thickness of a few nanometers, it may be formed by an ALD method as opposed to a conventional thin film deposition method. Formation of the second oxide film using the ALD method will be described later.

In the third operation 64, an upper electrode is formed on the second oxide film. The upper electrode may be a TiN electrode or may be an Si electrode doped with a conductive dopant.

FIG. 5 is a block diagram for describing in more detail a second operation 62 in the manufacture of a capacitor depicted in FIG. 4. Referring to FIG. 5, the second operation 62 may be further divided into three sub-operations 62a, 62b and 62c. A detailed method of forming the second oxide film using an ALD method is performed in the sub-operations 62a, 62b and 62c. In an embodiment of the present invention, the second oxide film is an La₂O₃ film.

More specifically, in the first sub-operation 62a, a precursor including a metal component, e.g., La, of the second oxide film, such as (La(tmhd)₃, La(N(Si(Me)₃)₂)₃ or La(iPrCp)₃, is deposited on the first oxide film. Subsequently, the precursor layer is formed by performing a first exhaust process and removing remaining precursors from the reaction chamber.

In the second sub-operation 62b, the precursor layer is oxidized. More specifically, an oxidation gas, such as water vapor, is supplied to the reaction chamber after the first exhaust process. Then, the second oxide film, i.e., the La₂O₃ film, is formed on the lower electrode through a substitution reaction between the oxidation gas and the precursor layer, i.e., oxidation of the precursor layer. Subsequently, an unreacted portion of the oxidation gas in the reaction chamber is removed by performing a second exhaust process.

In the third sub-operation 62c, impurities are removed from the second oxide film. More specifically, excess water vapor included in the second oxide film is removed by supplying ozone (O₃) to the reaction chamber after performing the second exhaust process. Subsequently, a third exhaust process is performed to remove remaining O₃ from the reaction chamber.

The third sub-operation 62c is regarded as a drying process because the water vapor included in the second oxide film is removed.

The third sub-operation 62c is also regarded as a second oxidation process because the precursor layer can further be oxidized by the supplied O₃ while removing impurities. During the formation of the second oxide film, the first and second oxidation processes may be repeated.

Table 1 illustrates whether a second oxide film is formed, whether water vapor remains in the second oxide film, and a leakage current density in the second oxide film according to the oxidation process used to form the second oxide film on the lower electrode using an ALD method.

TABLE 1
Oxidation Process

| | O₃ | H₂O | H₂O→O₃ | O₃→H₂O |
|---|---|---|---|---|
| Film Formation? | no | yes | yes | no |
| Water Vapor (H₂O) Inclusion? | − | yes | no | − |
| Leakage Current Density | − | 10⁻¹ | 10⁻⁷ | − |
| (A/cm²) | | | | |

Referring to Table 1, the second oxide film is not formed on the lower electrode when O₃ is used as the oxidation gas or when water vapor (H₂O) is supplied to the reaction chamber after supplying the ozone.

When the water vapor (H₂O) is used as the oxidation gas, the second oxide film is formed on the lower electrode. However, the water vapor (H₂O) is included in the formed second oxide film and the leakage current density is as high as 10⁻¹ A/cm₂.

On the contrary, when O₃ is supplied to the chamber after supplying the water vapor (H₂O) according to the method of manufacturing the capacitor according to an embodiment of the present invention, not only is the second oxide film formed on the lower electrode, but the water vapor (H₂O) does not remain, i.e., is not included, in the formed second oxide film and the leakage current density is as low as 10⁻⁷ A/cm₂.

A semiconductor memory device including the capacitor depicted in FIG. 2A according to an exemplary embodiment of the present invention will now be described.

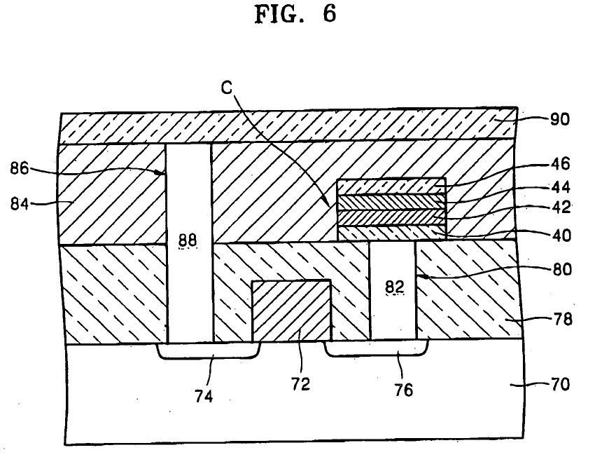

FIG. 6 illustrates a cross-sectional view of a semiconductor device according to an embodiment of the present invention including the capacitor depicted in FIG. 2A.

Referring to FIG. 6, the memory device includes first and second doped regions 74 and 76 doped with a conductive dopant in a substrate 70. The first and second doped regions 74 and 76 are separated by a predetermined distance. The first region 74 is a source region and the second region 76 is a drain region. A channel region is formed between the two regions 74 and 76 on the substrate 70, and a gate stack 72 is disposed on the channel region. The gate stack 72 turns the channel region on or off according to a voltage applied to the gate stack 72. The gate stack 72 includes a gate insulating film (not shown) and a gate conductive layer (not shown). The substrate 70, the first and second regions 74 and 76, and the gate stack 72 constitute a MOSFET. A first interlayer insulating layer 78 covers the gate stack 72 and part of the substrate 70. A first contact hole 80 that exposes a portion of the second region 76 is formed in the first interlayer insulating layer 78. The first contact hole 80 is filled with a first conductive plug 82, e.g., polysilicon doped with a conductive dopant. A capacitor C is formed on the first conductive plug 82 and the first interlayer insulating layer 78 and covers the entire surface of the first conductive plug 82. The capacitor C may be the capacitor C depicted in FIG. 2A or another capacitor according to an embodiment of the present invention. Accordingly, descriptions of detailed structure and performance of the capacitor C will not be repeated. The lower electrode 40 and the first conductive plug 82 may be formed of the same conductive material, or may be formed of different conductive materials. A second interlayer insulating layer 84 is formed on the capacitor C and the first interlayer insulating layer 78 and covers the capacitor C. A second contact hole 86 that exposes a portion of the first region 74 is formed in the first interlayer insulating layer 78 and the second interlayer insulating layer 84. The second contact hole 86 is filled with a second conductive plug 88. The second conductive plug 88 may be formed of polysilicon doped with a conductive dopant, or may be formed of a different conductive material. A conductive layer 90 is formed on the second conduction plug 88 and the second interlayer insulating layer 84, and covers an entire surface of the second conductive plug 88. The nconductive layer 90 is a bit line and crosses the gate stack 72. The conductive layer 90 and the second conductive plug 88 may be formed of the same conductive material, or may be formed of different conductive materials.

Since the above-described memory device includes the capacitor C of FIG. 2A, data stored in the capacitor C can be maintained for a long time in a normal state, thereby increasing reliability of the memory device.

The capacitor according to the exemplary embodiment of the present invention includes a reaction barrier film that prevents an unwanted reaction between an oxide film, which includes a metal element, e.g., a lanthanide element, and is used as a dielectric film, and a lower and/or an upper electrode including silicon. Accordingly, electrical degradation of the capacitor due to silicate formation as a result of a reaction between the metal element in the oxide film and the silicon can be avoided. In the process of forming the oxide film using an ALD method, water vapor is completely removed by ozone after the formation of the oxide film. Resultantly, the oxide film is completely dried. Thus, electrical degradation of the capacitor due to inclusion of water vapor in the oxide film is prevented. Moreover, a memory device including a capacitor according to an embodiment of the present invention can store data for a relatively long time without loss, thereby increasing the reliability of the memory device.

Exemplary embodiments of the present invention have been disclosed herein and, although specific terms are employed, they are used and are to be interpreted in a generic and descriptive sense only and not for purpose of limitation. For example, in the capacitor according to an embodiment of the present invention, the first dielectric film may alternatively be a non-oxide film that can prevent a reaction between an oxide film and an upper and/or lower electrode including silicon. Also, the upper and lower electrodes may alternatively be formed of a material that does not include silicon, and the dielectric film can be replaced by an La₂O₃ film. Accordingly, it will be understood by those of ordinary skill in the art that various changes in form and details may be made without departing from the spirit and scope of the present invention as set forth in the following claims.

1. A capacitor of a semiconductor device, comprising:
a lower electrode;
a dielectric film on the lower electrode;
an upper electrode on the dielectric film; and
a first reaction barrier film for preventing a reaction between the lower electrode and the dielectric film, the first reaction barrier film being interposed between the lower electrode and the dielectric film.

2. The capacitor as claimed in claim 1, wherein the lower electrode is one of a silicon (Si) electrode doped with a conductive dopant and a titanium nitride (TiN) electrode.

3. The capacitor as claimed in claim 1, wherein the first reaction barrier film has positive ions with smaller radii than positive ions of the dielectric film.

4. The capacitor as claimed in claim 1, wherein the first reaction barrier film is one of a hafnium oxide (HfO₂) film and an aluminum oxide (Al₂O₃) film.

5. The capacitor as claimed in claim 4, wherein the dielectric film is an oxide film including a metal element.

6. The capacitor as claimed in claim 1, wherein the dielectric film is an oxide film including a metal element.

7. The capacitor as claimed in claim 6, wherein the metal element is a lanthanide element.

8. The capacitor as claimed in claim 6, wherein the oxide film including the metal element is a lanthanum oxide (La₂O₃) film.

9. The capacitor as claimed in claim 1, wherein the upper electrode is one of a silicon (Si) electrode doped with a conductive dopant and a titanium nitride (TiN) electrode.

10. The capacitor as claimed in claim 1, further comprising a second reaction barrier film between the upper electrode and the dielectric film, wherein the upper electrode is a silicon (Si) electrode doped with a conductive dopant.

11. The capacitor as claimed in claim 10, wherein the second reaction barrier film has positive ions with smaller radii than positive ions of the dielectric film.

12. The capacitor as claimed in claim 10, wherein the second reaction barrier film is one of a hafnium oxide (HfO₂) film and an aluminum oxide (Al₂O₃) film.

13. The capacitor as claimed in claim 1, wherein the dielectric film has a thickness of between about 2 to 10 nm.

14. The capacitor as claimed in claim 1, wherein the first reaction barrier film has a thickness of about 2 nm.

15. The capacitor as claimed in claim 1, wherein the dielectric film has a thickness greater than that of the first reaction barrier film.

16. A method of forming a capacitor, comprising:
forming a lower electrode;
forming a first reaction barrier film on the lower electrode;
forming a precursor layer including a metal element on the first reaction barrier film;
forming an oxide film including the metal element by oxidizing the precursor layer;
drying the oxide film; and
forming an upper electrode on the dried oxide film.

17. The method as claimed in claim 16, wherein forming the precursor layer comprises depositing a precursor on the first reaction barrier layer.

18. The method as claimed in claim 17, wherein the precursor is one of (La(tmhd)₃, La(N(Si(Me)₃)₂)₃ or La(iPrCp)₃.

19. The method as claimed in claim 16, wherein forming the first reaction barrier film comprises forming an oxide film to a thickness of about 2 nm using an atomic layer deposition (ALD).

20. The method as claimed in claim 16, wherein the first reaction barrier film is one of hafnium oxide (HfO₂) and aluminum oxide (Al₂O₃).

21. The method as claimed in claim 16, further comprising, before forming the upper electrode, forming a second reaction barrier film on the dried oxide film.

22. The method as claimed in claim 21, wherein the lower electrode and the upper electrode are each one of a silicon (Si) electrode doped with a conductive dopant and a titanium nitride (TiN) film.

23. The method as claimed in claim 16, wherein the lower electrode is formed of a silicon (Si) electrode doped with a conductive dopant, and the upper electrode is formed of a titanium nitride (TiN) film.

24. The method as claimed in claim 16, wherein the lower and upper electrodes are a titanium nitride (TiN) film.

25. The method as claimed in claim 16, further comprising performing an exhaust process after forming the precursor layer.

26. The method as claimed in claim 16, further comprising performing an exhaust process after forming the oxide film.

27. The method as claimed in claim 16, further comprising performing an exhaust process after drying the oxide film.

28. The method as claimed in claim 16, wherein forming the oxide film comprises flowing an oxidation gas over the precursor layer to firstly oxidize the precursor layer.

29. The method as claimed in claim 28, wherein the oxidation gas is water vapor.

30. The method as claimed in claim 28, wherein the metal element is a lanthanide element.

31. The method as claimed in claim 28, wherein forming the oxide film further comprises supplying ozone (O₃) over the firstly oxidized precursor layer to secondly oxidize the firstly oxidized precursor layer.

32. The method as claimed in claim 31, wherein the metal element is a lanthanide element.

33. The method as claimed in claim 31, wherein, in forming the oxide film, the first and second oxidations are repeated.

34. The method as claimed in claim 16, wherein the metal element is a lanthanide element.

35. The method as claimed in claim 16, wherein drying the oxide film comprises flowing ozone (O₃) over the oxide film.

36. The method as claimed in claim 16, wherein the first reaction barrier film has positive ions with smaller radii than positive ions of the dielectric film.

37. The method as claimed in claim 21, wherein the second reaction barrier film has positive ions with smaller radii than positive ions of the dielectric film.

38. The method as claimed in claim 37, wherein the second reaction barrier film is one of a hafnium oxide (HfO₂) film and an aluminum oxide (Al₂O₃) film.

39. A semiconductor memory device including a capacitor connected to a transistor, wherein the capacitor comprises:
a lower electrode;
a dielectric film on the lower electrode;
an upper electrode on the dielectric film; and
a first reaction barrier film for preventing a reaction between the lower electrode and the dielectric film, the first reaction barrier film being interposed between the lower electrode and the dielectric film.

40. The semiconductor memory device as claimed in claim 39, wherein the lower electrode and the upper electrode are each one of a silicon (Si) electrode doped with a conductive dopant and a titanium nitride (TiN) film.

41. The semiconductor memory device as claimed in claim 39, wherein the first reaction barrier film has positive ions with smaller radii than positive ions of the dielectric film.

42. The semiconductor memory device as claimed in claim 39, wherein the first reaction barrier film is one of a hafnium oxide (HfO₂) film and an aluminum oxide (Al₂O₃) film.

43. The semiconductor memory device as claimed in claim 39, further comprising a second reaction barrier film between the upper electrode and the dielectric film.

44. The semiconductor memory device as claimed in claim 39, wherein the dielectric film is an oxide film including a metal element.

45. The semiconductor memory device as claimed in claim 39, wherein the metal element is a lanthanide element.

46. The semiconductor memory device as claimed in claim 43, wherein the second reaction barrier film has positive ions with smaller radii than positive ions of the dielectric film.

47. The semiconductor memory device as claimed in claim 43, wherein the second reaction barrier film is one of a hafnium oxide (HfO₂) film and an aluminum oxide (Al₂O₃) film.

48. The semiconductor memory device as claimed in claim 43, wherein the dielectric film is an oxide film including a metal element.

49. The semiconductor memory device as claimed in claim 48, wherein the metal element is a lanthanide element.
